(19) United States
(12) Patent Application Publication
(10) Pub. No.: US 2008/0079088 A1
(43) Pub. Date: Apr. 3, 2008

(54) Semiconductor device and method for manufacturing the same

(76) Inventor: Chiaki Kudo, Hyogo (JP)

Correspondence Address: MCDERMOTT WILL & EMERY LLP, 600 13TH STREET, NW, WASHINGTON, DC, 20005-3096, US

(21) Appl. No.: 11/806,878

(22) Filed: Jun. 5, 2007

(30) Foreign Application Priority Data
Sep. 28, 2006 (JP) 2006-264196

(51) Int. Cl. H01L 27/088; H01L 21/8234

(52) U.S. Cl. 257/384; 438/294; 257/E27.06; 257/E21.622; 257/E21.628

(57) ABSTRACT

A semiconductor device includes an active region and a dummy active region formed in a semiconductor substrate to have a distance from each other, an isolation region formed between the active region and the dummy active region and has a top surface lower than top surfaces of the active region and the dummy active region, a gate insulating film formed on the active region and a fully silicided gate electrode formed on the isolation region, the gate insulating film and the dummy active region through full silicidation of a silicon gate material film with metallic material.

### BACKGROUND OF THE INVENTION

1. Field of the Invention

The present invention relates to a semiconductor device and a method for manufacturing the same. In particular, it relates to a semiconductor device including fully silicided (FUSI) field effect transistors and a method for manufacturing the same.

2. Description of Related Art

The degree of integration of semiconductor elements in a semiconductor device is becoming higher and higher, for example, by designing gate electrodes for MIS (metal-insulator-semiconductor) field effect transistors (FET: field-effect transistors) under finer rules and forming a gate insulating film with highly dielectric material to reduce the thickness thereof in an electrical sense. However, in general, polysilicon used for the gate electrodes inevitably causes depletion even if impurities are injected therein. Further, the depletion leads to increase in thickness of the gate insulating film in an electrical sense. This has been an obstacle to improvement in performance of the FETs.

In recent years, a gate electrode structure that allows prevention of the depletion has been proposed. For example, as an effective means of preventing the depletion of the gate electrodes, it has been reported that silicon material for forming the gate electrodes is reacted with metallic material to cause silicidation to obtain fully silicided (FUSI) gate electrodes.

Hereinafter, explanation of steps for forming the FUSI gate electrodes according to a conventional method for manufacturing MISFETs is provided (for example, see Unexamined Japanese Patent Publication No. 2000-252426).

First, as shown in FIG. 8A, an isolation region 102 is formed in an upper portion of a silicon semiconductor substrate 101 and a gate insulating film 104 and a gate electrode 105A made of silicon material are formed on an active region 103T2 defined by the isolation region 102 formed in the semiconductor substrate 101. Then, shallow source/drain diffusion layers are formed in parts of the active region 103T2 on both sides of the gate electrode 105A. Sidewall spacers 106 are formed on both sides of the gate electrode 105A. Then, deep source/drain diffusion layers are formed in parts of the active region 103T2 outside the sidewall spacers 106. The shallow and deep source/drain diffusion layers constitute source/drain regions 103a.

Then, an interlayer insulating film 107 is deposited to cover the entire surface of the semiconductor substrate 101 as shown in FIG. 8B and planarized by CMP (chemical mechanical polishing) until the silicon gate electrode 105A is exposed as shown in FIG. 8C.

Then, as shown in FIG. 9A, metallic material 108 made of cobalt (Co) is deposited on the interlayer insulating film 107 from which the gate electrode 105A is exposed. After that, the semiconductor substrate 101 is subjected to RTA (rapid thermal annealing) to cause reaction between the silicon gate electrode 105A and the metallic material 108, thereby obtaining a fully silicided gate electrode 105 made of cobalt silicide (CoSi₂). Then, an unreacted part of the metallic material 108 is selectively removed by etching.

The inventor of the present invention has conducted a close study of conventional FUSI structures and has found that full silicidation of the silicon material forming the gate electrodes in the MISFET does not occur uniformly. This phenomenon occurs irrespective of whether the gate width is relatively large or small. Explanation of the phenomenon is provided below in detail.

FIG. 10 is a plan view of a major part illustrating the structure of the conventional semiconductor device. FIG. 10 corresponds to FIG. 8C illustrating the step of exposing the gate electrode 105A shown in FIG. 8C. FIG. 8C is a sectional view taken along the line VIIIc-VIIIc of FIG. 10.

Referring to FIG. 10, the silicon gate electrode 105A provided with the sidewall spacers 106 on both sides thereof is configured to extend across the isolation region 102 formed in the semiconductor substrate 101 and the active regions 103T1 and 103T2 including the source/drain regions 103a formed in the upper portion thereof. The top surface of the gate electrode 105A is exposed in the interlayer insulating film 107.

The top surface of the isolation region 102 which defines the active regions 103T1 and 103T2 often comes higher than the top surface of the semiconductor substrate 101 due to variations in manufacture. As shown in FIG. 11A which is a sectional view taken along the line XIa-XIa of FIG. 10, the top surface of the active region 103T1 where the gate width of the gate electrode 105A is relatively small is buried with the silicon material forming the gate electrode 105A. In this case, thickness t1 of part of the silicon material on the active region 103T1 becomes larger than thickness t2 of part of the silicon material on the isolation region 102. Further, on the active region 103T2 where the gate width of the gate electrode 105A is relatively large, part of the silicon material forming the gate electrode 105A in the middle of the active region 103T2 has thickness t2, which is smaller than the thickness of part of the silicon material in the vicinity of the isolation region 102 surrounding the active region 103T2. Therefore, in the step of planarizing the interlayer insulating film 107 by CMP, the interlayer insulating film 107 may possibly remain in part of the active region 103T2 where the silicon material forming the gate electrode 105A is relatively thin, i.e., in a recess formed in the top surface of the gate electrode 105A.

Therefore, in the subsequent step of depositing the metallic material 108 and performing RTA to obtain the fully silicided gate electrode 105, part of the silicon material forming the gate electrode 105A may remain unreacted on the active region 103T1 where the gate width of the gate electrode 105A is relatively small as shown in FIG. 11B because the part is relatively thick and the silicidation is not fully achieved. Further, on the active region 103T2 where the gate width of the gate electrode 105A is relatively large, the silicidation may not occur at all because the interlayer insulating film 107 remains.

As the fully silicided gate electrode 105 cannot be obtained with uniform composition according to the conventional art, variations in threshold voltage of the MISFETs have been inevitable.

### SUMMARY OF THE INVENTION

In view of the above, an object of the present invention is to provide a semiconductor device having FUSI gate electrodes of uniform composition irrespective of the gate width and a method for manufacturing the same.

To achieve the object, a semiconductor device according to an aspect of the present invention is a semiconductor device including a first active region and a first dummy active region formed in the semiconductor substrate to have a distance from each other; a first isolation region formed in part of the semiconductor substrate between the first active region and the first dummy active region and has a top surface lower than top surfaces of the first active region and the first dummy active region; a first gate insulating film formed on the first active region; and a first fully silicided gate electrode formed on the first isolation region, the first gate insulating film and the first dummy active region through full silicidation of a silicon gate material film with metallic material.

As to the semiconductor device according to the aspect of the present invention, the first dummy active region is formed to have a distance from the first active region and the top surface of the first isolation region is lower than the top surfaces of the first active region and the first dummy active region. Therefore, the silicon gate material film is formed on the first active region with uniform thickness. As a result, the ratio of the thickness of the silicon gate material film and the thickness of the metallic material is kept uniform over the first active region and the reaction between the silicon gate material film and the metallic material occurs substantially uniformly. Thus, the first fully silicided gate electrode is provided with uniform composition.

As to the semiconductor device according to the aspect of the present invention, it is preferable that the distance between the first active region and the first dummy active region is smaller than the double of a thickness of the silicon gate material film.

This configuration makes it possible to prevent a recess that hinders the reaction between the silicon gate material film and the metallic material from generating in the silicon gate material film deposited on the first isolation region between the first active region and the first dummy active region.

As to the semiconductor device according to the aspect of the present invention, it is preferable that a dimension of the first dummy active region in the direction of a gate length of the first fully silicided gate electrode is not smaller than the gate length of the first fully silicided gate electrode and not larger than a dimension of the first active region in the gate length direction. Further, it is preferable that a dimension of the first dummy active region in the direction of a gate length of the first fully silicided gate electrode is equal to a dimension of the first active region in the gate length direction.

As to the semiconductor device according to the aspect of the present invention, it is preferable that part of the silicon gate material film which is not fully silicided is left on the top surface of the first isolation region.

If the silicon gate material film is partially left in this manner, capacitance value of the first fully silicided gate electrode with respect to the semiconductor substrate is reduced. This contributes to improvement in performance of the semiconductor device.

As to the semiconductor device according to the aspect of the present invention, it is preferable that the semiconductor device further includes a second MIS transistor formed on the semiconductor substrate, the second MIS transistor including: a second active region formed in part of the semiconductor substrate on the side of the first active region opposite to the first dummy active region to have a distance from the first-active region; a second isolation region formed in part of the semiconductor substrate between the second active region and the first active region and has a top surface lower than top surfaces of the first active region and the second active region; a second gate insulating film formed on the second active region; and a second fully silicided gate electrode formed on the second isolation region and the second gate insulating film through full silicidation of the silicon gate material film with the metallic material to be continuous with the first fully silicided gate electrode and have a gate width different from that of the first fully silicided gate electrode.

With this configuration, the silicon gate material film is deposited in uniform thickness on the first and second active regions where the first and second MIS transistors are formed. Therefore, irrespective of the gate width of the first and second fully silicided gate electrodes, the first and second fully silicided gate electrodes are provided with uniform composition. Therefore, the first and second MIS transistors are achieved while reducing variations in threshold voltage.

As to the semiconductor device according to the aspect of the present invention, it is preferable that the semiconductor device further includes a second dummy active region formed in part of the semiconductor substrate on the side of the second active region opposite to the first active region to have a distance from the second active region; and a third isolation region formed in part of the semiconductor substrate between the second active region and the second dummy active region and has a top surface lower than top surfaces of the second active region and the second dummy active region.

With this configuration, the first and second fully silicided gate electrodes are provided with more uniform composition irrespective of the gate width of the first and second fully silicided gate electrodes. As a result, the first and second MIS transistors are achieved while reducing variations in threshold voltage to a further extent.

As to the semiconductor device according to the aspect of the present invention, it is preferable that the distance between the second active region and the second dummy active region is smaller than the double of the thickness of the silicon gate material film.

This configuration makes it possible to prevent a recess that hinders the reaction between the silicon gate material film and the metallic material from generating in the silicon gate material film deposited on the third isolation region between the second active region and the second dummy active region.

As to the semiconductor device according to the aspect of the present invention, it is preferable that a dimension of the second dummy active region in the direction of a gate length of the second fully silicided gate electrode is not smaller than the gate length of the second fully silicided gate electrode and not larger than a dimension of the second active region in the gate length direction. Further, it is preferable that a dimension of the second dummy active region in the direction of a gate length of the second fully silicided gate electrode is equal to a dimension of the second active region in the gate length direction.

As to the semiconductor device according to the aspect of the present invention, it is preferable that part of the silicon gate material film which is not fully silicided is left on the top surface of the second isolation region.

If the silicon gate material film is partially left in this manner, capacitance value of the second fully silicided gate electrode with respect to the semiconductor substrate is reduced. This contributes to improvement in performance of the semiconductor device.

A method for manufacturing a semiconductor device according to the aspect of the present invention includes the steps of: (a) forming a first active region and a first dummy active region in a semiconductor substrate to have a distance from each other; (b) forming a first isolation region in part of the semiconductor substrate between the first active region and the first dummy active region; (c) bringing a top surface of the first isolation region lower than top surfaces of the first active region and the first dummy active region; (d) forming a first gate insulating film on the first active region; (e) forming a patterned silicon gate material film on the first isolation region, the first gate insulating film and the first dummy active region; (f) forming an interlayer insulating film on the semiconductor substrate to cover the silicon gate material film and planarizing the interlayer insulating film to expose a top surface of the silicon gate material film; (g) providing metallic material on the interlayer insulating film and the exposed part of the silicon gate material film; and (h) performing full silicidation of the silicon gate material film with the metallic material to form a first fully silicided gate electrode on the first active region.

By the method according to the aspect of the present invention, the first dummy active region is formed to have a distance from the first active region and the top surface of the first isolation region is lower than the top surfaces of the first active region and the first dummy active region. Therefore, the silicon gate material film is formed on the first active region with uniform thickness. As a result, the ratio of the thickness of the silicon gate material film and the thickness of the metallic material is kept uniform over the first active region and the reaction between the silicon gate material film and the metallic material occurs substantially uniformly. Thus, the first fully silicided gate electrode is provided with uniform composition.

As to the method according to the aspect of the present invention, it is preferable that the step (a) is performed such that the distance between the first active region and the first dummy active region becomes smaller than the double of a thickness of the silicon gate material film.

This configuration makes it possible to prevent a recess that hinders the reaction between the silicon gate material film and the metallic material from generating in the silicon gate material film deposited on the first isolation region between the first active region and the first dummy active region.

As to the method according to the aspect of the present invention, it is preferable that the step (a) includes the step of forming a second active region in part of the semiconductor substrate on the side of the first active region opposite to the first dummy active region to have a distance from the first active region, the step (b) includes the step of forming a second isolation region between the first active region and the second active region, the step (c) includes the step of bringing a top surface of the second isolation region lower than top surfaces of the first active region and the second active region, the step (d) includes the step of forming a second gate insulating film on the second active region, the step (e) includes the step of forming the silicon gate material film on the second gate insulating film and the second isolation region and the step (g) includes the step of performing full silicidation of the silicon gate material film with the metallic material to form a second fully silicided gate electrode having a gate width different from that of the first fully silicided gate electrode on the second active region.

With this configuration, the silicon gate material film is deposited in uniform thickness on the first and second active regions where the first and second MIS transistors are formed. Therefore, irrespective of the gate width of the first and second fully silicided gate electrodes, the first and second fully silicided gate electrodes are provided with uniform composition. Therefore, the first and second MIS transistors are achieved while reducing variations in threshold voltage.

As to the method according to the aspect of the present invention, it is preferable that the step (a) further includes the step of forming a second dummy active region in part of the semiconductor substrate on the side of the second active region opposite to the first active region to have a distance from the second active region, the step (b) further includes the step of forming a third isolation region between the second active region and the second dummy active region, the step (c) further includes the step of bringing a top surface of the third isolation region lower than top surfaces of the second active region and the second dummy active region and the step (e) further includes the step of forming the silicon gate material film on the second dummy active region and the third isolation region.

With this configuration, the first and second fully silicided gate electrodes are provided with more uniform composition irrespective of the gate width of the first and second fully silicided gate electrodes. As a result, the first and second MIS transistors are achieved while reducing variations in threshold voltage to a further extent.

As to the method according to the aspect of the present invention, it is preferable that the step (a) is performed such that the distance between the second active region and the second dummy active region becomes smaller than the double of a thickness of the silicon gate material film.

This configuration makes it possible to prevent a recess that hinders the reaction between the silicon gate material film and the metallic material from generating in the silicon gate material film deposited on the third isolation region between the second active region and the second dummy active region.

As to the method according to the aspect of the present invention, it is preferable that the step (h) includes the step of leaving part of the silicon gate material film unreacted with the metallic material during the full silicidation.

If the silicon gate material film is partially left in this manner, capacitance value of the first fully silicided gate electrode with respect to the semiconductor substrate is reduced. This contributes to improvement in performance of the semiconductor device.

Thus, as described above, the semiconductor device and the method for manufacturing the same according to the present invention make it possible to achieve fully silicided gate electrodes with uniform composition irrespective of the gate width thereof. Therefore, variations in threshold voltage are reduced.

### BRIEF DESCRIPTION OF THE DRAWINGS

FIG. 1 is a plan view of a major part illustrating the structure of a semiconductor device according to an embodiment of the present invention.

FIG. 2A is a sectional view of a major part illustrating the structure of the semiconductor device according to the embodiment of the present invention and FIG. 2B is a sectional view of a major part illustrating a modification of the structure of the semiconductor device according to the embodiment of the present invention, both of which taken along the line IIa-IIa shown in FIG. 1.

FIGS. 3A and 3B are plan views of a major part illustrating the modification of the structure of the semiconductor device according to the embodiment of the present invention.

FIGS. 4A to 4C are sectional views of a major part illustrating a method for manufacturing the semiconductor device according to the embodiment of the present invention.

FIGS. 5A to 5C are sectional views of a major part illustrating the method for manufacturing the semiconductor device according to the embodiment of the present invention.

FIGS. 6A and 6B are a plan view and a sectional view of a major part illustrating the method for manufacturing the semiconductor device according to the embodiment of the present invention.

FIGS. 7A to 7C are sectional views of a major part illustrating the method for manufacturing the semiconductor device according to the embodiment of the present invention.

FIGS. 8A to 8C are sectional views of a major part illustrating a method for manufacturing a conventional semiconductor device.

FIGS. 9A and 9B are sectional views of a major part illustrating the method for manufacturing the conventional semiconductor device.

FIG. 10 is a sectional view of a major part illustrating a general structure of the conventional semiconductor device.

FIGS. 11A and 11B are sectional views of a major part illustrating the structure of a semiconductor device to explain the problem to be solved by the present invention.

### DETAILED DESCRIPTION OF THE INVENTION

Hereinafter, explanation of a semiconductor device and a method for manufacturing the same according to an embodiment of the present invention is provided with reference to the drawings.

First, the structure of the semiconductor device according to the embodiment of the present invention is described below.

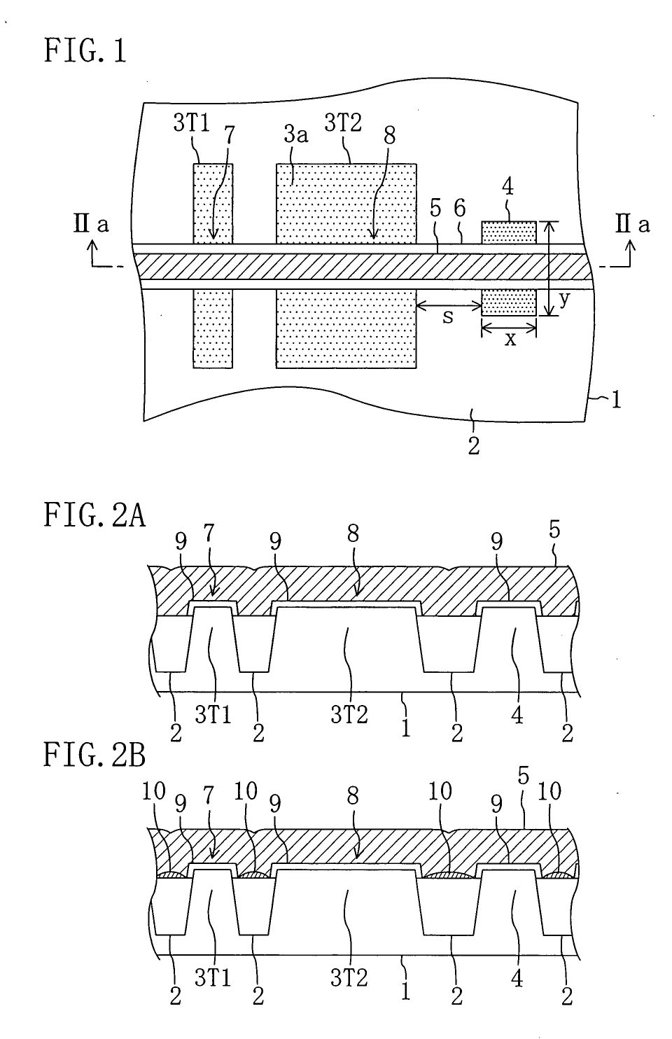

FIG. 1 is a plan view of a major part illustrating the structure of the semiconductor device according to the embodiment of the present invention.

As shown in FIG. 1, active regions 3T1 and 3T2 having p-wells (not shown) and an isolation region 2 surrounding the active regions 3T1 and 3T2 are formed in the main surface of a silicon semiconductor substrate 1. The isolation region 2 may be formed by a shallow trench isolation technique. N-type source/drain regions 3a are formed in upper portions of the active region 3T1 (a second active region) and the active region 3T2 (a first active region). A dummy active region (a first dummy active region) 4 having a p-well (not shown) is also formed in the main surface of the semiconductor substrate 1 and surrounded by the isolation region 2. The dummy active region 4 is opposed to the active region 3T2 with the isolation region 2 interposed therebetween to have a distance S from the active region 3T2 (part of the isolation region 2 between the active region 3T2 and the dummy active region 4 corresponds to a first isolation region). The distance S between the active region 3T2 and the dummy active region 4 is smaller than the double of the thickness of a silicon gate material film for forming a fully silicided gate electrode 5 to be described later. This configuration makes it possible to prevent a recess from generating in the silicon gate material film deposited on the isolation region 2 between the active region 3T2 and the dummy active region 4.

A fully silicided gate electrode 5 is formed on the semiconductor substrate 1 to cross the active regions 3T1 and 3T2 and the dummy active region 4 which are formed in the semiconductor substrate 1 and divided from each other by the isolation region 2. The fully silicided gate electrode 5 is made of silicide obtained by reaction between the silicon gate material film and metallic material (detailed later). Sidewall spacers 6 made of a silicon nitride film are formed on both sides of the fully silicided gate electrode 5. Thus, a first FET 7 having a small gate width is formed on the active region 3T1 whose dimension in the gate width direction is small, while a second FET 8 having a larger gate width than the first FET 7 is formed on the active region 3T2 whose dimension in the gate width direction is larger than the active region 3T1.

It is preferable that the dummy active region 4 is arranged to at least partially intersect with the fully silicided gate electrode 5. More specifically, dimension x of the dummy active region 4 in the gate width direction is preferably not smaller than the minimum dimension as the active region and dimension y of the dummy active region 4 in the gate length direction is preferably not smaller than the sum of the gate length of the fully silicided gate electrode 5 and an allowance for misalignment with the fully silicided gate electrode 5. It is preferable to form the dummy active region 4 in the minimum size within the above-described range because if the dummy active region 4 becomes large, capacitance value of the fully silicided gate electrode 5 and wires (not shown) with respect to the semiconductor substrate 1 increases and the performance of the semiconductor device may deteriorate.

As shown in FIG. 2A, which is a sectional view of a major part taken along the line IIa-IIa of FIG. 1 for illustrating the structure of the semiconductor device according to the embodiment of the invention, a HfO₂ gate insulating film 9 is formed on the active regions 3T1 and 3T2 and the dummy active region 4 which are formed in the semiconductor substrate 1 and defined by the isolation region 2. The top surface of the isolation region 2 is lower than the top surfaces of the active regions 3T1 and 3T2 and the dummy active region 4 (the top surface of the semiconductor substrate 1). The fully silicided gate electrode 5 is formed on the isolation region 2 and the gate insulating film 9 to cross the active regions 3T1 and 3T2 and the dummy active region 4 divided from each other by the isolation region 2 (part of the isolation region 2 between the active regions 3T1 and 3T2 corresponds to a second isolation region).

FIG. 2A shows the structure in which the fully silicided gate electrode 5 is formed through a complete reaction between the silicon gate material film and metallic material. This structure reduces wiring resistance and therefore contributes to improvement in performance of the device. However, as shown in FIG. 2B, it may be possible that unreacted portions of the silicon gate material film 10 remain on the isolation region 2 due to insufficient reaction between the silicon gate material film and the metallic material. More specifically, since the FETs are not formed on the isolation region 2, silicide obtained on the isolation region 2 may have different composition from that of the silicide forming the fully silicided gate electrode 5 on the active regions 3T1 and 3T2. In fact, the remaining of the silicon gate material film 10 reduces the capacitance value of the fully silicided gate electrode 5 with respect to the semiconductor substrate 1, which contributes to the improvement in performance of the semiconductor device.

In the thus-configured semiconductor device according to the embodiment of the present invention, the top surface of the isolation region 2 is lower than the top surfaces of the active regions 3T1 and 3T2 and the dummy active region 4 and the dummy active region 4 is arranged to have a distance S from the active region 3T2. As a result, on the isolation region 2 whose top surface is lower than the fop surfaces of the active regions 3T1 and 3T2, the silicon gate material film is deposited without generating a recess that hinders the silicidation in the top surface thereof. Further, on the active regions 3T1 and 3T2 where the first and second FETs 7 and 8 are formed, the silicon gate material film is deposited with uniform thickness. Therefore, irrespective of the two-dimensional sizes of the active regions 3T1 and 3T2, i.e., regardless of the gate width of the fully silicided gate electrode 5, the fully silicided gate electrode 5 is provided with uniform composition. Thus, the FETs are obtained with reduced variations in threshold value.

### —Modification—

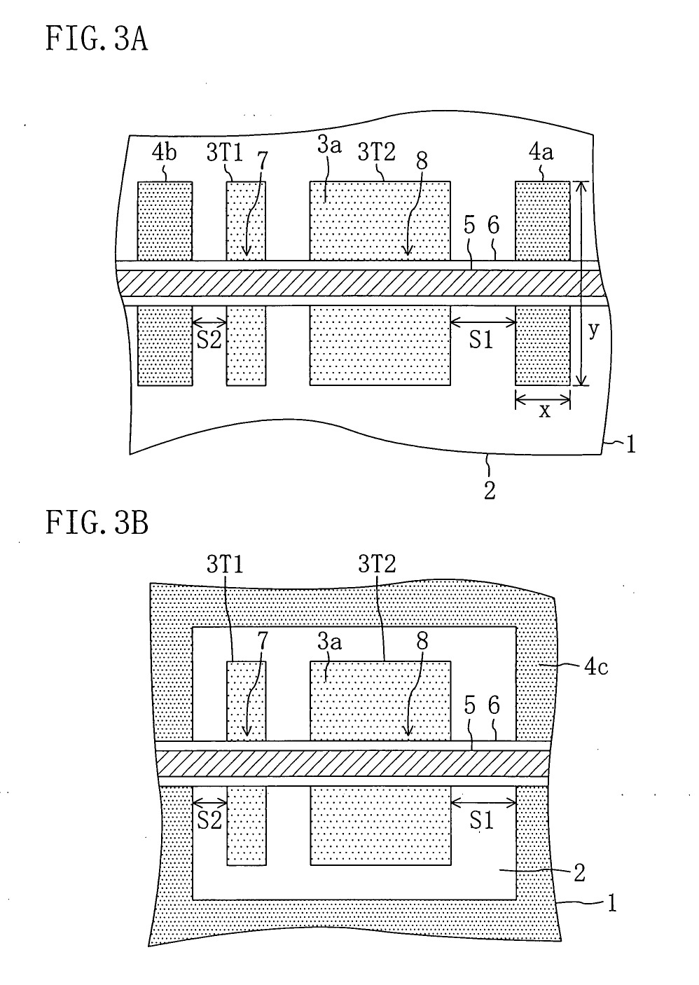

FIGS. 3A and 3B are plan views of a major part illustrating a modification of the structure of the semiconductor device according to the embodiment of the present invention.

The modified structure shown in FIGS. 3A and 3B is the same as that shown in FIG. 1 except that the location of the dummy active region 4 is different from that shown in FIG. 1.

As shown in FIG. 3A, a dummy active region 4a is formed opposite the active region 3T2 with the isolation region 2 interposed therebetween to have a distance SI from the active region 3T2. Further, a dummy active region 4b (a second dummy active region) is formed opposite the active region 3T1 with the isolation region 2 interposed therebetween to have a distance S2 from the active region 3T1. With this configuration, the effect of the dummy active region 4a opposed to the active region 3T2 is also obtained by the dummy active region 4b opposed to the active region 3T1. In FIG. 3A, the dimension y of the dummy active regions 4a and 4b in the gate length direction is depicted as the same as the dimension of the active regions 3T1 and 3T2 in the gate length direction. However, the dimensions x and y of the dummy active regions 4a and 4b are not particularly limited as long as they are within the range described above.

In order to obtain the same effect achieved by the provision of the dummy active regions 4a and 4b opposed to the active regions 3T2 and 3T1, respectively, a dummy active region 4c may be provided around the periphery of the isolation region 2 while keeping the distances S1 and S2 from the active regions 3T2 and 3T1 in the gate width direction, respectively. The location of the dummy active region 4 is not limited to the above and it may be arranged anywhere as long as the distances S1 and S2 from the active regions 3T2 and 3T1 in the gate width direction, the dimension x of the dummy active region 4 in the gate width direction and the dimension y of the dummy active region 4 in the gate length direction are within the suitable range.

Hereinafter, a method for manufacturing the semiconductor device according to the embodiment of the present invention is explained.

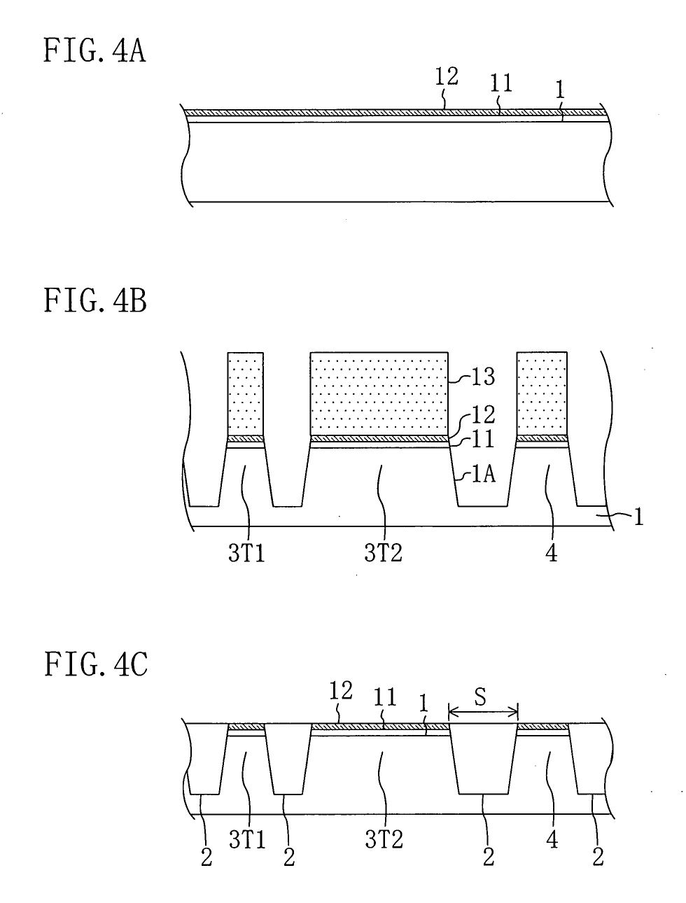

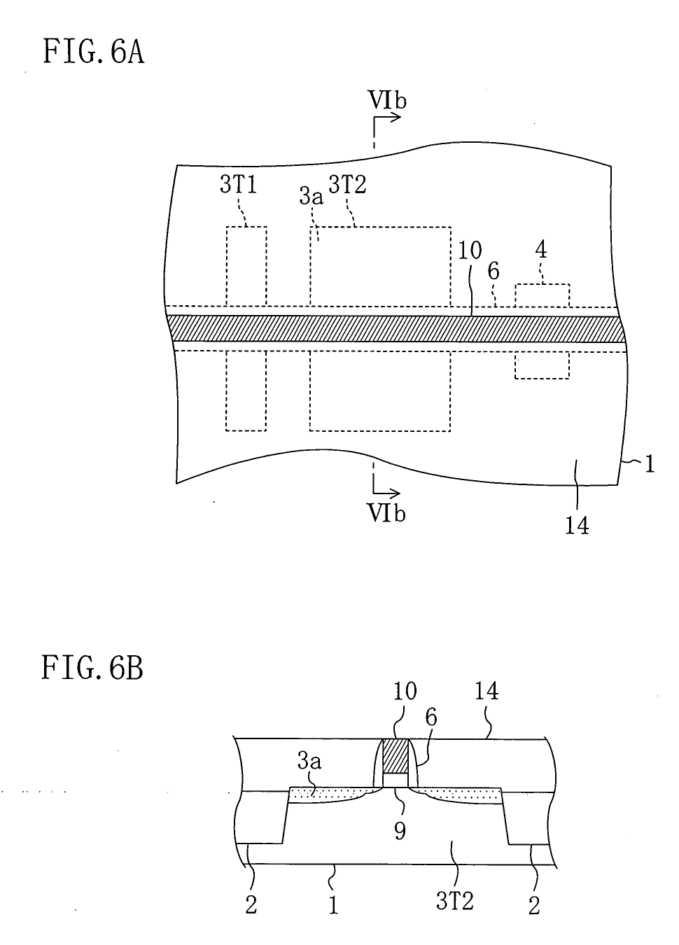

FIGS. 4A to 4C, 5A to 5C, 6A and 6B and 7A to 7C are sectional or plan views for illustrating the manufacturing method according to the embodiment of the present invention step by step. FIGS. 4A to 4C, 5A to 5C and 7A to 7C are sectional views taken along the line IIa-IIa of FIG. 1. FIG. 6A is a plan view and FIG. 6B is a sectional view taken along the line VIb-VIb shown in FIG. 6A.

First, as shown in FIG. 4A, p-wells (not shown) are formed in a silicon semiconductor substrate 1 by ion implantation and a protective oxide film 11 and a nitride film 12 are formed in this order on the semiconductor substrate 101.

Then, a resist 13 for defining active regions 3T1 and 3T2 and a dummy active region 4 to be described later is formed and the nitride film 12 and the protective oxide film 11 are etched using the resist 13 as a mask. Further, the semiconductor substrate 1 is also etched down to a predetermined depth to form an isolation groove 1A as shown in FIG. 4B. The isolation groove 1A defines the active regions 3T1 and 3T2 and the dummy active region 4. It is preferable that the dummy active region 4 is arranged to at least partially intersect with a fully silicided gate electrode 5 described later. More specifically, dimension x of the dummy active region 4 in the gate width direction is preferably not smaller than the minimum dimension as the active region and dimension y of the dummy active region 4 in the gate length direction is preferably not smaller than the sum of the gate length of the fully silicided gate electrode 5 and an allowance for misalignment with the fully silicided gate electrode 5. It is preferable to form the dummy active region 4 in the minimum size within the above-described range because if the dummy active region 4 becomes large, capacitance value of the fully silicided gate electrode 5 and wires (not shown) with respect to the semiconductor substrate 1 increases and the performance of the semiconductor device may deteriorate. The dummy active region 4 may be arranged as shown in FIGS. 3A and 3B mentioned above.

After the resist 13 is removed, an isolation insulation film is deposited on the entire surface of the semiconductor substrate 1 by CVD, for example, and then planarized by CMP until the surface of the nitride film 12 is exposed. Thus, the isolation insulation film is buried the isolation groove 1A to form an isolation region 2 as shown in FIG. 4C. A distance S depicted in the figure, i.e., a distance S between the active region 3T2 and the dummy active region 4, is smaller than the double of the thickness of a silicon gate material film deposited to form a fully silicided gate electrode 5 in a later step. This configuration makes it possible to prevent a recess from generating in the silicon gate material film deposited on the isolation region 2 between the active region 3T2 and the dummy active region 4. In the present embodiment, the silicon gate material film 10 is deposited to 100 nm in thickness and the distance S is set to 150 nm.

Although the isolation region 2 described above is formed by a general STI technique, it may be formed by stacking a protective oxide film, a polysilicon film and a nitride film. Alternatively, the isolation region 2 may have a laminated structure formed by oxidizing the surface of the semiconductor substrate 1 and depositing an isolation insulation film thereon. Explanation of thermal treatment and the like is omitted, though they may be performed in some cases.

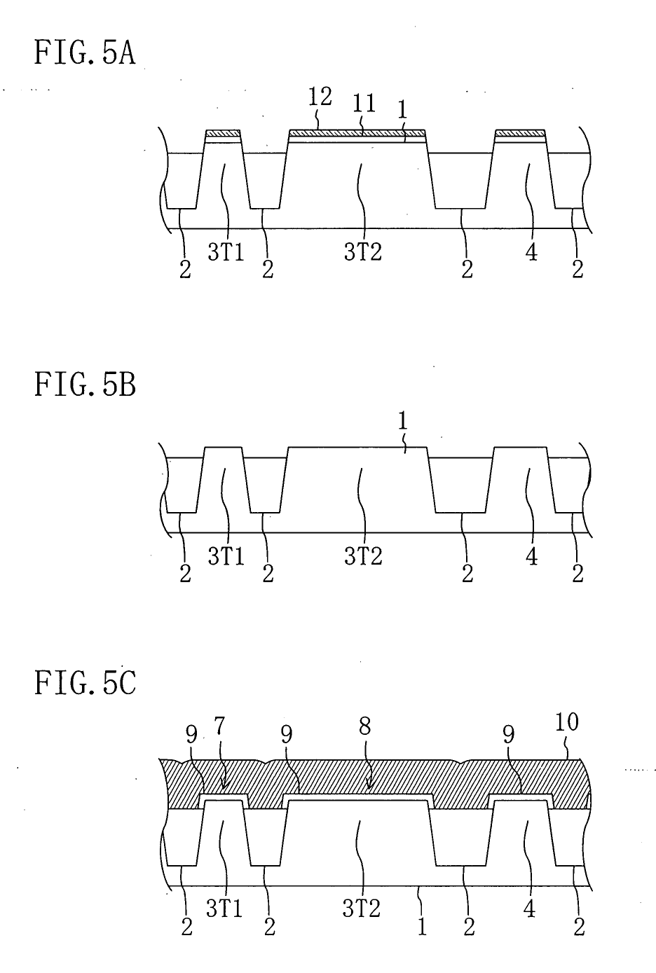

Then, as shown in FIG. 5A, the top surface of the isolation region 2 is etched down using a hydrogen fluoride solution. The etching is performed to bring the top surface of the isolation region 2 lower than the top surface of the semiconductor substrate 1, i.e., the top surfaces of the active regions 3T1 and 3T2 and the dummy active region 4.

Then, as shown in FIG. 5B, the nitride film 12 is removed using a phosphoric acid solution and the protective oxide film 11 is removed using a hydrogen fluoride solution. As a result, the top surfaces of the active regions 3T1 and 3T2 and the dummy active region 4 are exposed.

Then, a HfO₂ film for forming a gate insulating film is formed on the active regions 3T1 and 3T2 and the dummy active region 4 by CVD. Further, a polysilicon film is deposited up to 100 nm on the isolation region 2 and the HfO₂ film. A resist (not shown) for forming a gate electrode crossing the active regions 3T1 and 3T2 and the dummy active region 4 is formed by lithography and the HfO₂ film and the polysilicon film are etched using the resist pattern as a mask. Thus, a gate insulating film 9 and a silicon gate material film 10 are obtained as shown in FIG. 5C. Then, the resist pattern is removed. In this configuration, the active region 3T2 and the dummy active region 4 have the above-described distance S between them, i.e., a distance smaller than the double of the thickness of the silicon gate material film 10, and the top surface of the isolation region 2 is lower than the top surface of the semiconductor substrate 1. This configuration makes it possible to prevent a recess that hinders the silicidation from generating in the silicon gate material film 10 deposited on the isolation region 2 between the active region 3T2 and the dummy active region 4, thereby making the top surface of the silicon gate material film 10 substantially flat.

Then, according to a known method, sidewalls 6 are formed on both sides of the silicon gate material film 10 and n-type source/drain regions 3a are formed in parts of the active regions 3T1 and 3T2 on both sides of the silicon gate material film 10. An interlayer insulating film 14 made of a silicon oxide film is then formed on the entire surface of the semiconductor substrate 1 by CVD and planarized by CMP until the top surface of the silicon gate material film 10 is exposed. Thus, the structure shown in FIGS. 6A and 6B is obtained. Since the silicon gate material film 10 has the substantially flat top surface as described above, the top surface of the silicon gate material film 10 formed to cross the active regions 3T1 and 3T2 and the dummy active region 4 is exposed by planarizing the interlayer insulating film 14 as shown in the plan view of FIG. 6A and the sectional view of FIG. 6B taken along the VIb-VIb of FIG. 6A, irrespective of the sizes of the active regions 3T1 and 3T2 and the dummy active region 4.

The sidewalls 6 and the source/drain regions 3a may be formed by implanting n-type impurity ions using the silicon gate material film 10 as a mask. More specifically, n-type shallow source/drain layers are formed in parts of the active regions 3T1 and 3T2 on both sides of the silicon gate material film 10. A silicon nitride film is then deposited on the entire surface of the semiconductor substrate 1 by CVD and anisotropically etched to provide the sidewalls 6 on both sides of the silicon gate material film 10. Subsequently, n-type impurity ions are implanted using the sidewalls 6 as a mask and thermal treatment is performed to form n-type deep source/drain diffusion layers in parts of the active regions 3T1 and 3T2 on both sides of the sidewalls 6. The shallow and deep n-type source/drain diffusion layers provide the n-type source/drain regions 3a. The ion implantation for forming the shallow source/drain diffusion layers may be performed using the silicon gate material film 10 and offset spacers formed on both sides of the silicon gate material film 10 as a mask. In this case, the sidewalls 6 are formed on the offset spacers formed on the both sides of the silicon gate material film 10. The sidewalls 6 may be made of a layered film of a silicon oxide film and a silicon nitride film.

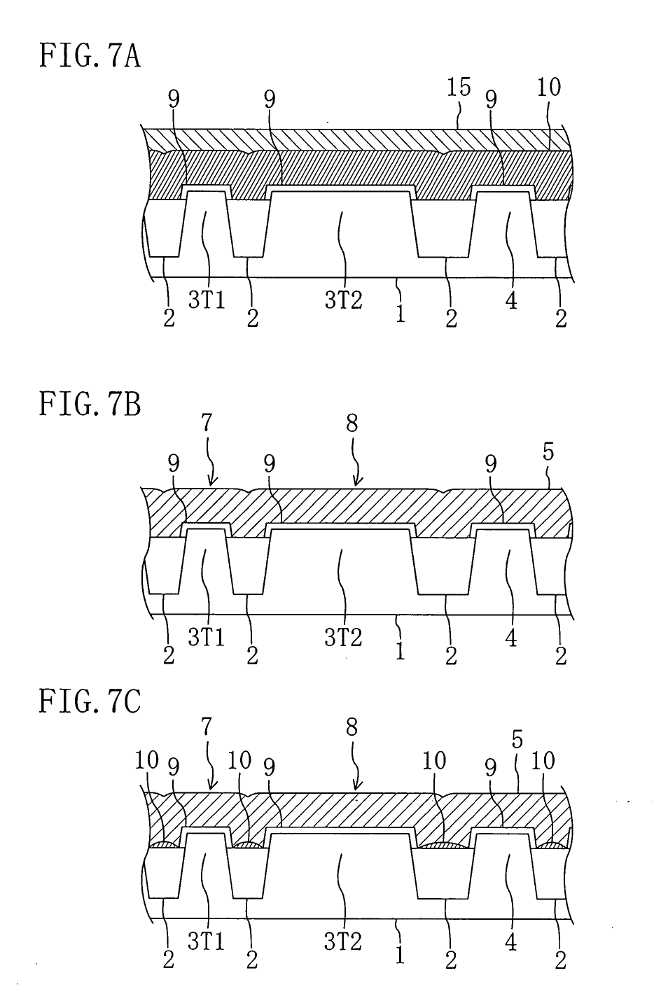

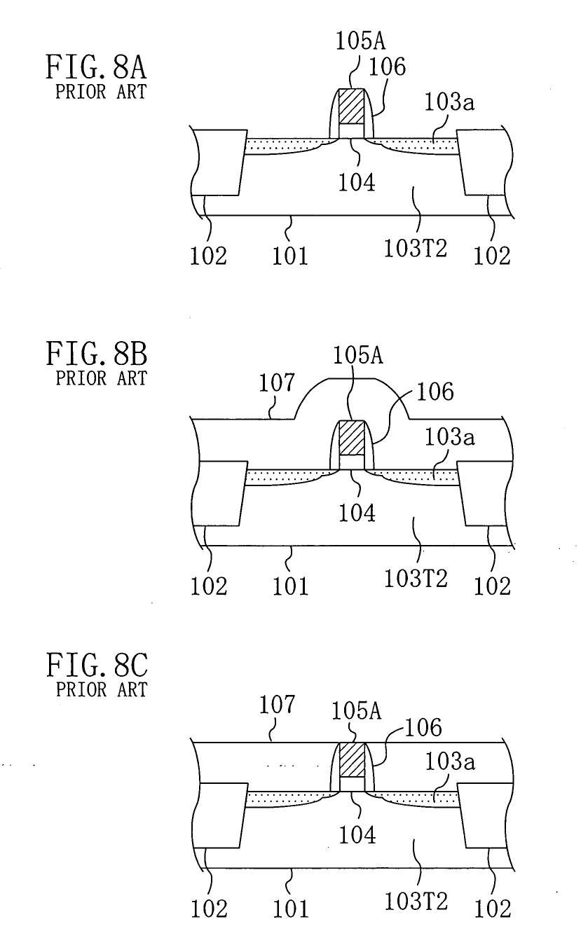

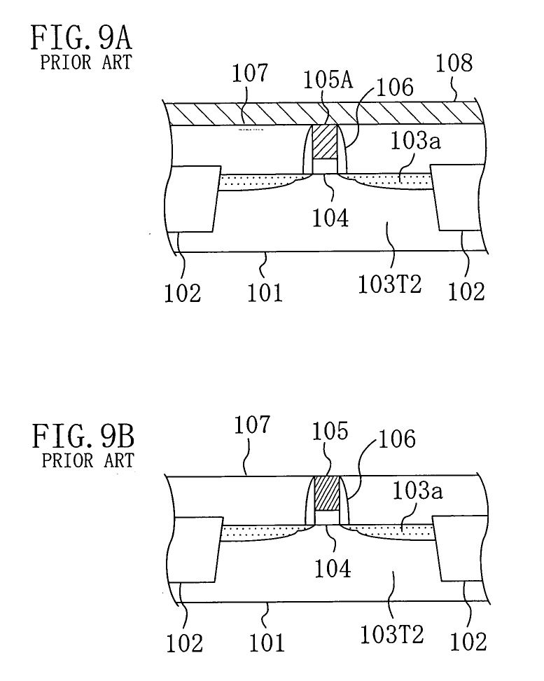

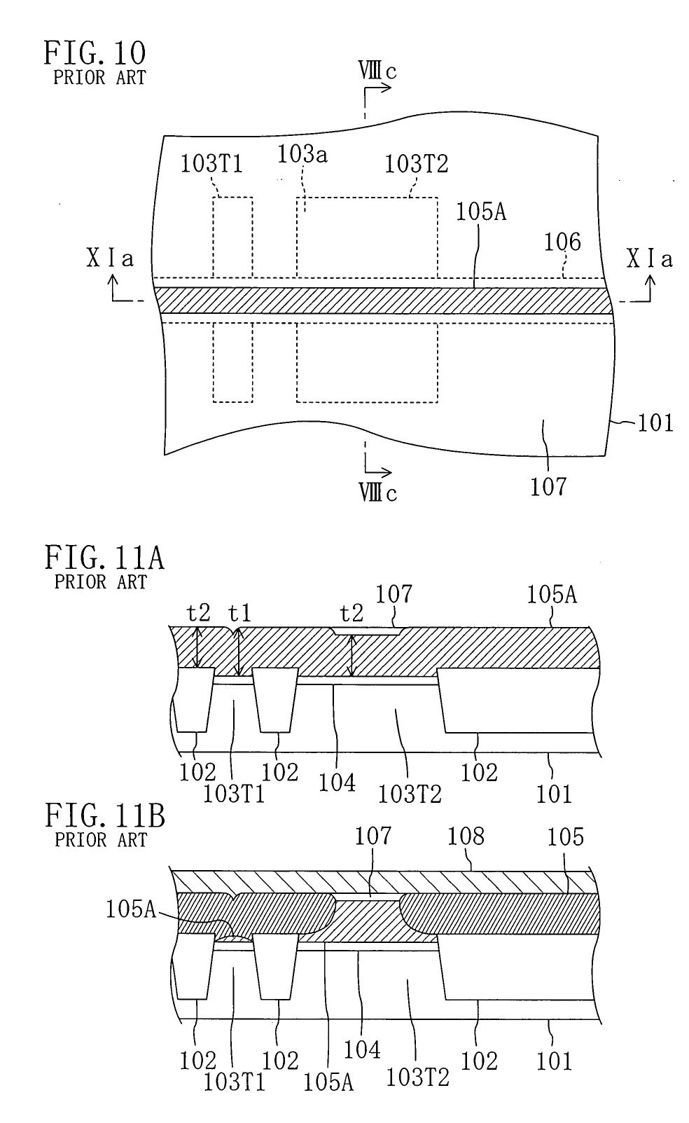

Subsequently, as shown in FIG. 7A, metallic material 15 such as nickel (Ni) is deposited to 70 nm on the interlayer insulating film 14 and the exposed silicon gate material film 10 by sputtering. The metallic material 15 is deposited to a sufficient thickness to cause full silicidation of at least part of the silicon gate material film 10 on the active regions 3T1 and 3T2.

Then, as shown in FIG. 7B, thermal treatment such as rapid thermal annealing (RTA) is performed in nitrogen atmosphere at 400° C. to cause silicidation between the metallic material 15 and the silicon gate material film 10, thereby obtaining a fully silicided gate electrode 5. Thus, first and second FETs 7 and 8 are formed on the active regions 3T1 and 3T2, respectively. The silicidation does not occur between the source/drain region 3a and the metallic material 15 because the interlayer insulating film 14 is interposed therebetween. Then, unreacted part of the metallic material 15 is removed by selective etching. Further, an interlayer insulating film, contact plugs and metal wires are formed by a known method.

FIG. 7B illustrates the case where the fully silicided gate electrode 5 is formed by full silicidation between the silicon gate material film 10 and the metallic material 15. Since this structure reduces the wiring resistance, it contributes to improvement in performance of the device. However, the case of FIG. 7C is also acceptable, in which the reaction between the silicon gate material film 10 and the metallic material 15 is not completely achieved and unreacted portions of the silicon gate material film 10 are left on the isolation region 2. For example, as shown in FIG. 7C, the difference in height between the top surface of the isolation region 2 and the top surface of the semiconductor substrate 1 may be increased in the step shown in FIG. 5A, or alternatively, the thickness of the metallic material 15 may be controlled such that part of the silicon gate material film 10 on the isolation region 2 is not fully silicided in the step shown in FIG. 7A such that the silicon gate material film 10 is left or a fully silicided gate electrode 5 of different composition is formed on the isolation region 2. Even in such a case, the fully silicided gate electrodes 5 on the active regions 3T1 and 3T2 always have the same composition irrespective of the sizes (two-dimensional sizes) of the active regions 3T1 and 3T2. Since the FETs are not formed on the isolation region 2, there will be no problem even if the silicide formed on the isolation region 2 has different composition from the silicide constituting the fully silicided gate electrodes 5 on the active regions 3T1 and 3T2. Moreover, if the gate silicon layer 10 remains on the isolation region 2, the capacitance value of the fully silicided gate electrodes 5 with respect to the semiconductor substrate 1 is reduced. This contributes to the improvement in performance of the semiconductor device.

Thus, according to the method of the present embodiment, the top surface of the isolation region 2 is set lower than the top surfaces of the active regions 3T1 and 3T2 and the dummy active region 4 and the dummy active region 4 is arranged to have a distance S from the active region 3T2. As a result, on the isolation region 2 whose top surface is lower than the top surfaces of the active regions 3T1 and 3T2, the silicon gate material film is deposited while preventing the generation of a recess that hinders the silicidation in the top surface thereof. Further, on the active regions 3T1 and 3T2 where the first and second FETs 7 and 8 are formed, the silicon gate material film 10 is deposited with uniform thickness. Therefore, irrespective of the two-dimensional sizes of the active regions 3T1 and 3T2, i.e., regardless of the gate width of the fully silicided gate electrode 5, the fully silicided gate electrode 5 is provided with uniform composition. As a result, the first and second FETs 7 and 8 having the same and uniform composition are simultaneously formed on the single semiconductor substrate 1. Thus, the FETs are obtained with reduced variations in threshold value.

In the embodiment of the present invention, description is made only on the first and second FETs 7 and 8 formed on the substrate for explanation's sake. However, it should be understood that a larger number of elements are formed on the semiconductor substrate 1. The first and second FETs 7 and 8 are not limited to the conductivity type described above and they may be either of N— or P-type FETs.

Instead of oxide hafnium (HfO₂) used as the material for the gate insulating film 9, HfSiO, HfSiON, SiO₂ or SiON may be used. Further, nickel used as the metallic material 9 may be replaced with titanium (Ti), cobalt (Co), platinum (Pt) or a compound thereof.

The semiconductor device and the method for manufacturing the same according to the present invention are useful as a semiconductor device including field-effect transistors having FUSI gate electrodes and a method for manufacturing the same.

What is claimed is:

1. A semiconductor device including a first MIS transistor on a semiconductor substrate, wherein the first MIS transistor comprising:
a first active region and a first dummy active region formed in the semiconductor substrate to have a distance from each other;
a first isolation region formed in part of the semiconductor substrate between the first active region and the first dummy active region and has a top surface lower than top surfaces of the first active region and the first dummy active region;
a first gate insulating film formed on the first active region; and
a first fully silicided gate electrode formed on the first isolation region, the first gate insulating film and the first dummy active region through full silicidation of a silicon gate material film with metallic material.

2. The semiconductor device of claim 1, wherein
the distance between the first active region and the first dummy active region is smaller than the double of a thickness of the silicon gate material film.

3. The semiconductor device of claim 1, wherein
a dimension of the first dummy active region in the direction of a gate length of the first fully silicided gate electrode is not smaller than the gate length of the first fully silicided gate electrode and not larger than a dimension of the first active region in the gate length direction.

4. The semiconductor device of claim 1, wherein
a dimension of the first dummy active region in the direction of a gate length of the first fully silicided gate electrode is equal to a dimension of the first active region in the gate length direction.

5. The semiconductor device of claim 1, wherein
part of the silicon gate material film which is not fully silicided is left on the top surface of the first isolation region.

6. The semiconductor device of claim 1 further includes a second MIS transistor formed on the semiconductor substrate, the second MIS transistor comprising:
a second active region formed in part of the semiconductor substrate on the side of the first active region opposite to the first dummy active region to have a distance from the first active region;
a second isolation region formed in part of the semiconductor substrate between the second active region and the first active region and has a top surface lower than top surfaces of the first active region and the second active region;
a second gate insulating film formed on the second active region; and
a second fully silicided gate electrode formed on the second isolation region and the second gate insulating film through full silicidation of the silicon gate material film with the metallic material to be continuous with the first fully silicided gate electrode and have a gate width different from that of the first fully silicided gate electrode.

7. The semiconductor device of claim 6 further comprising:
a second dummy active region formed in part of the semiconductor substrate on the side of the second active region opposite to the first active region-to have a distance from the second active region; and
a third isolation region formed in part of the semiconductor substrate between the second active region and the second dummy active region and has a top surface lower than top surfaces of the second active region and the second dummy active region.

8. The semiconductor device of claim 7, wherein
the distance between the second active region and the second dummy active region is smaller than the double of the thickness of the silicon gate material film.

9. The semiconductor device of claim 6, wherein
a dimension of the second dummy active region in the direction of a gate length of the second fully silicided gate electrode is not smaller than the gate length of the second fully silicided gate electrode and not larger than a dimension of the second active region in the gate length direction.

10. The semiconductor device of claim 6, wherein
a dimension of the second dummy active region in the direction of a gate length of the second fully silicided gate electrode is equal to a dimension of the second active region in the gate length direction.

11. The semiconductor device of claim 6, wherein
part of the silicon gate material film which is not fully silicided is left on the top surface of the second isolation region.

12. A method for manufacturing a semiconductor device comprising the steps of:
(a) forming a first active region and a first dummy active region in a semiconductor substrate to have a distance from each other;
(b) forming a first isolation region in part of the semiconductor substrate between the first active region and the first dummy active region;
(c) bringing a top surface of the first isolation region lower than top surfaces of the first active region and the first dummy active region;
(d) forming a first gate insulating film on the first active region;
(e) forming a patterned silicon gate material film on the first isolation region, the first gate insulating film and the first dummy active region;
(f) forming an interlayer insulating film on the semiconductor substrate to cover the silicon gate material film and planarizing the interlayer insulating film to expose a top surface of the silicon gate material film;
(g) providing metallic material on the interlayer insulating film and the exposed part of the silicon gate material film; and
(h) performing full silicidation of the silicon gate material film with the metallic material to form a first fully silicided gate electrode on the first active region.

13. The method of claim 12, wherein
the step (a) is performed such that the distance between the first active region and the first dummy active region becomes smaller than the double of a thickness of the silicon gate material film.

14. The method of claim 12, wherein
the step (a) includes the step of forming a second active region in part of the semiconductor substrate on the side of the first active region opposite to the first dummy active region to have a distance from the first active region,
the step (b) includes the step of forming a second isolation region between the first active region and the second active region,
the step (c) includes the step of bringing a top surface of the second isolation region lower than top surfaces of the first active region and the second active region,
the step (d) includes the step of forming a second gate insulating film on the second active region,
the step (e) includes the step of forming the silicon gate material film on the second gate insulating film and the second isolation region and
the step (g) includes the step of performing full silicidation of the silicon gate material film with the metallic material to form a second fully silicided gate electrode having a gate width different from that of the first fully silicided gate electrode on the second active region.

15. The method of claim 14, wherein
the step (a) further includes the step of forming a second dummy active region in part of the semiconductor substrate on the side of the second active region opposite to the first active region to have a distance from the second active region,
the step (b) further includes the step of forming a third isolation region between the second active region and the second dummy active region,
the step (c) further includes the step of bringing a top surface of the third isolation region lower than top surfaces of the second active region and the second dummy active region and
the step (e) further includes the step of forming the silicon gate material film on the second dummy active region and the third isolation region.

16. The method of claim 15, wherein
the step (a) is performed such that the distance between the second active region and the second dummy active region becomes smaller than the double of a thickness of the silicon gate material film.

17. The method of claim 12, wherein
the step (h) includes the step of leaving part of the silicon gate material film unreacted with the metallic material during the full silicidation.
